(19) United States
(12) Patent Application Publication
(10) Pub. No.: US 2026/0328622 A1
(43) Pub. Date: Oct. 22, 2026

(54) THERMAL RADIATION DETECTOR

(71) Applicant: CENTRE NATIONAL DE LA RECHERCHE SCIENTIFIQUE, Paris (FR)

(72) Inventors: Jean-Luc GARDEN, Echirolles (FR); Charlotte LATARGEZ, Echirolles (FR); Daniel BOURGAULT, Saint Nizier Du Moucherotte (FR); Gaël MOIROUX, VIF (FR)

(21) Appl. No.: 19/100,501

(22) PCT Filed: Jul. 27, 2023
(86) PCT No.: PCT/EP2023/070916

§ 371 Date: Jan. 31, 2025

(30) Foreign Application Priority Data
Aug. 1, 2022 (FR) FR2207983

(51) Int. Cl. G01J 5/14; H10N 10/01; H10N 10/851; H10N 10/852

(52) U.S. Cl. CPC G01J 5/14; H10N 10/01; H10N 10/852; H10N 10/8556

(57) ABSTRACT

Thermoelectric microsensor formed by a stack of layers including a support made from thermally conductive material, a layer of a dielectric material, at least one pair of layers, forming a thermocouple, the two layers of which are separated, by a trench, by a minimum distance greater than 500 nm, and a layer of metal partially covering the at least one pair of layers. The layer of metal includes a central portion that covers a portion of each of the two layers of the at least one pair of layers adjacent to the trench. A central portion of one of the two layers of the at least one pair of layers covers a central portion of the other layer of the at least one pair of layers. The microsensor has a parameter ZT_{effective} of between 0.1 and 1.9, where ZT is the merit factor of the microsensor.

### TECHNICAL FIELD

The present invention relates to the field of high-resolution thermoelectric sensors for measuring low-power thermal radiations.

### PRIOR ART

Thermal detectors based on the principle of thermoelectric detection are known in the prior art. However, these detectors are insufficiently sensitive and do not make it possible to measure powers below one microwatt.

The thermal detector according to the invention makes it possible to overcome this problem by offering high sensitivity and a low detection threshold. This is because the thermal detector according to the invention is able to measure variations in temperature of between a few microkelvins and a few tens of millikelvins or variations in thermal radiation of between a few nanowatts and a few hundreds of microwatts.

High-resolution detectors based on photodiodes the measuring principle of which is quantal are also known in the prior art. One problem with such sensors lies in the fact that detection is centred solely on a small range of wavelengths that is particular to each photodiode. Another problem with photodiode detectors is the complexity of use thereof and the need to calibrate the detector at each use.

The thermal detector according to the invention makes it possible to overcome these problems by making it possible to measure radiations over a wide wavelength band ranging from ultraviolet to medium and far infrared. Furthermore, the thermal detector according to the invention has great ease of use.

Finally, microbolometers the measuring principle of which is based on variation in electrical resistance as a function of temperature are known in the prior art. Microbolometers have great detection sensitivity. On the other hand, they are very expensive and, to have great sensitivity, require complex conditions of use with cooling of the measuring electronics and of the detector. They can be adapted to measurements of radiations at ambient temperature but, in this case, they lack sensitivity.

The thermal detector according to the invention for its part has a low manufacturing cost. It can operate in a wide range of temperatures and, in particular, at ambient temperature while keeping an exceptional level of sensitivity. Finally, the thermal detector according to the invention does not require cooling of the detector or of the measuring electronics.

Another aim of the invention is furthermore to propose a thermal detector with rapid response, i.e. having a response time of the order of one second to a few milliseconds.

### PRESENTATION OF THE INVENTION

For this purpose, a thermoelectric microsensor is proposed for measuring low-power thermal radiations, referred to as a microsensor, formed by a stack of layers comprising, from a bottom face to a top face of the microsensor:
a support made from thermally conductive material,
a layer consisting of a dielectric material,
at least one pair of layers forming a thermocouple, the at least one pair of layers is preferably arranged so that a trench separates, preferably completely or only partly, the two layers of the at least one pair of layers by a minimum distance greater than 500 nm,
a layer of metal partially covering the at least one pair of layers, the layer of metal comprises two annular portions per pair of layers and for each thermocouple one of the two annular portions covers a peripheral portion of one of the two layers of the at least one pair of layers and the other one of the two annular portions covers a peripheral portion of the other layer of the at least one pair of layers.

In a first configuration of the microsensor, the microsensor is preferably arranged, and/or the at least one pair of layers is preferably arranged, and/or the layer of metal is preferably arranged, so that the layer of metal preferably comprises a central portion that covers at least one portion of preferably a top surface, of each of the two layers of the at least one pair of layers that is adjacent to the trench.

In a second configuration of the microsensor, the microsensor is preferably arranged, and/or the at least one pair of layers is preferably arranged, and/or the layer of metal is preferably arranged, so that a central portion of one of the two layers of the at least one pair of layers covers at least a central portion of the other layer of the at least one pair of layers.

The microsensor has, for a given interval of measurement temperatures, denoted [Tₘᵢₙ, Tₘₐₓ], a parameter ZT_{effective} of between 0.1 and 1.9, ZT is the merit factor of the microsensor and T is the measurement temperature.

Preferably, the materials constituting the two layers of the at least one pair of layers are selected so that, preferably, the arrangement of the microsensor according to the invention associated with the selection of the materials constituting the two layers of the at least one pair of layers are such that, for a given interval of measurement temperatures, denoted [Tₘᵢₙ, Tₘₐₓ], said microsensor has a parameter ZT_{effective} of between 0.1 and 1.9, ZT is the merit factor of the microsensor and T is the measurement temperature.

Unless indicated to the contrary, the whole of the description applies to the first and to the second configuration of the microsensor.

Microsensor can be understood to mean a sensor, a detector or a microdetector.

The support made from thermally conductive material may be a metal, for example copper, aluminium, silver or stainless steel, or glass or ceramic.

A layer of a pair of layers forming a thermocouple may comprise or consist of several different materials. A layer of a pair of layers forming a thermocouple may comprise several portions or segments each comprising or consisting of a different material. A layer in question of a pair of layers may comprise a first segment extending from an end, referred to as the proximal end, located on the same side as the centre of the microsensor of the layer in question, as far as half of the distance separating the proximal end from the end, referred to as the distal end, located on the same side as the external edge, of the layer in question, and a second segment extending from the distal end of the layer in question as far as the first segment. The first segment may consist of a material making it possible to obtain a high temperature gradient along the first segment and the second segment can consist of a material making it possible to obtain a temperature gradient lower than the first segment, or even a low temperature gradient.

Preferably, for the second configuration, the trench separates, only partly, the two layers of the at least one pair of layers by a minimum distance greater than 500 nm.

Preferably, for the second configuration, the proximal end of the layers of the at least one pair of layers corresponds to the central part of the layers of the at least one pair of layers.

Preferably, a trench, distinct from the trench separating, completely or only partly, the two layers of the at least one pair of layers, separates two adjacent layers of two different pairs of layers by a minimum distance greater than 500 nm.

Preferably, the centre of the microsensor constitutes the detection zone or sensitive zone of the microsensor.

In the second configuration, the layer of metal may furthermore cover the central portion of the layer of the at least one pair of layers covering the central portion of the other layer of the at least one pair of layers.

Preferably, the layer of metal does not extend over the whole of the top face of the microsensor. Preferably, the layer of metal is a discontinuous layer.

Preferably, the layer of metal may extend in all or part of the trench separating the two layers of the at least one pair of layers.

According to the invention, the term “pair of layers” corresponds to a pair of layers of a thermocouple of the microsensor.

According to the invention, the operating principle of a thermoelectric sensor can be defined as consisting in converting, successively, a radiation power into a thermal power and then the thermal power into a temperature gradient and then the temperature gradient into an electrical signal.

According to the invention, low-power thermal radiations can be understood as radiations the power of which is between a few tens of microwatts and a few tens of nanowatts.

Preferably, the layers of the stack of layers forming the microsensor are stacked along an axis extending between the bottom face and the top face of the microsensor.

According to the invention, top face of the microsensor can be understood to be the face or surface of the microsensor comprising, at least partly, the layer of metal. According to the invention, bottom face of the microsensor can be understood to be the face of the microsensor that is opposite to the top face of the microsensor.

Top face or surface, in particular of a layer in the stack of layers, can be understood to be the surface or the face oriented in the direction of the top face of the microsensor. Bottom face or surface, in particular of a layer in the stack of layers, can be understood to be the surface or face opposite to the top face or surface.

The top face or the bottom face of the microsensor can be oriented in the direction of the thermal radiation to be measured.

Preferably, the dielectric material has an electrical conductivity of less than 1.10⁻¹¹ S.m⁻¹.

Preferably, the dielectric material has a thermal conductivity of less than 1 W.m⁻¹.K⁻¹.

Preferably, the dielectric material is a polyimide membrane.

Preferably, in the first configuration, the two layers in a pair of layers are adjacent or adjoining, in particular at the centre of the microsensor. Preferably, in the first configuration, the two layers in a pair of layers are not in contact, preferably, and in particular, at the centre of the microsensor.

Preferably, a given layer in a pair of layers is separated from a layer in another pair of layers that is adjoining or adjacent to the given layer. Preferably, no layer in the at least one pair of layers is in contact with another layer in the at least one pair of layers.

Trench can be understood to mean a furrow or a space.

Preferably, in the first configuration, a distance separating two adjacent layers of one and the same pair of layers extends in a direction perpendicular to the direction of the stack of layers of the microsensor.

Preferably, a given layer in a pair of layers is separated by a trench or a space from a layer in another pair of layers that is adjoining or adjacent to the given layer. Preferably, a distance separating two adjacent layers of two different pairs of layers extends in a direction perpendicular to the direction of the stack of layers of the microsensor. Preferably, a distance separating two adjacent layers of two different pairs of layers extends along the length of the layers of the pairs of layers. Preferably, the distance separating two layers, which can be defined as a width of the trench or of the space, is between 0.5 μm and 100 μm.

Preferably, the sensitivity of the microsensor is proportional to the number of thermocouples, or of pairs of layers, that the microsensor comprises.

Preferably, the layer of metal partially covers a top surface of the at least one pair of layers. The layer of metal can comprise or consist of one or more metallic chemical elements.

Preferably, in the first configuration, the function of the central portion of the layer of metal is to provide an electrical connection between the two layers in the at least one pair of layers made from semiconductor material.

Preferably, the function of the central portion of the layer of metal is to allow better absorption of the thermal radiation to be measured.

Preferably, the layer of metal has a thermal conductivity greater than or equal to 10 W.m⁻¹.K⁻¹. Preferably, the layer of metal has an electrical conductivity greater than or equal to 1.10⁶ S.m⁻¹.

Preferably, in the first configuration, the portion of the layers in the at least one pair of layers that is adjacent to the trench does not coincide with a geometric centre of the microsensor. The geometric centre of the microsensor can coincide with a geometric centre of the layer of dielectric material. The centre of the microsensor can be included in an axis of revolution of the microsensor. The axis of revolution of the microsensor can be parallel to the direction of the stack of layers of the microsensor.

Preferably, in the second configuration, the geometric centre of the microsensor coincides with the central portion of the layer of the at least one pair of layers covering the central portion of the other layer of the at least one pair of layers.

Preferably, the ZT_{effective} of the microsensor is greater than or equal to 0.1, preferably again 0.2, preferably 0.3, preferably again 0.4, more preferably 0.5, even more preferably 0.6, particularly preferably 0.7, particularly advantageously 0.8 and very particularly advantageously 0.9. Advantageously, the ZT_{effectif} of the microsensor is equal to 1.

Preferably, the ZT_{effective} of the microsensor is less than or equal to 1.9, preferably again 1.8, preferably 1.7, preferably again 1.6, more preferably 1.5, even more preferably 1.4, particularly preferably 1.3, particularly advantageously 1.2, very particularly advantageously 1.1 and preferable above all 1.05.

The merit factor ZT_{effective} of the microsensor can be defined as the thermoelectric merit factor. In the prior art, the thermoelectric merit factor is used to evaluate the efficacy of the thermoelectric refrigeration modules, typically the efficacy of the Peltier modules. In this field, it is always sought to maximise the merit factor ZT_{effective} of the device to obtain maximum conversion efficiency.

According to the invention, the inventors have observed that the design of a thermal sensor arranged so that its ZT_{effective} is close to 1 or equal to 1 makes it possible to obtain the best sensitivity and the best detection threshold. The arrangement of the layers of the stack of layers of the microsensor as described above makes it possible to obtain a microsensor the ZT_{effective} of which is close to 1 or equal to 1.

Preferably, a thermal conductivity of the microsensor is less than or equal to 10 W.m⁻¹.K⁻¹.

Preferably, the thermal conductivity of the microsensor means the thermal conductivity measured between the two annular portions of the metal layer. Preferably, the thermal conductivity of the microsensor means the thermal conductivity measured between the two annular portions of each of the pairs of layers of the at least one pair of layers.

Preferably, the arrangement of the layers of the stack of layers of the microsensor as defined above makes it possible to minimise the thermal losses between the layers of the stack of layers of the microsensor but also between the microsensor and the environment thereof. Preferably, the arrangement of the layers of the stack of layers of the microsensor as defined above makes it possible to minimise the thermal losses along the axis of the stack of layers of the microsensor. Preferably, the arrangement of the layers of the stack of layers of the microsensor as defined above makes it possible to increase the sensitivity and the detection threshold of the microsensor. Furthermore, the arrangement of the layers of the stack of layers of the microsensor as defined above, although constituting an improvement of the invention, can contribute to obtaining a ZT_{effective} close to or equal to 1.

Preferably, a thermal time constant, denoted tau, of the microsensor is less than or equal to 10 s, tau is equal to the ratio between a calorific capacity of the microsensor and the thermal conductivity of the microsensor.

Preferably, the calorific capacity of the microsensor means the calorific capacity in a central zone of the microsensor. Preferably again, the calorific capacity of the microsensor means the calorific capacity of a central zone and/or of a portion of the layers of the stack of layers. The central zone of the microsensor can be defined as the zone of the microsensor when the power of the thermal radiation is absorbed.

Preferably, in the first configuration, the calorific capacity of the microsensor means the calorific capacity measured between the central portion of the metal layer and the portion of the layers of the at least one pair of layers covered by the central portion.

Preferably, in the second configuration, the calorific capacity of the microsensor means the calorific capacity measured between the central portion of the layer of the at least one pair of layers covering the central portion of the other layer of the at least one pair of layers.

Preferably, the arrangement of the layers of the stack of layers of the microsensor as defined above makes it possible to obtain such a thermal time constant. Preferably, the arrangement of the layers of the stack of layers of the microsensor as defined above making it possible to obtain such a thermal time constant makes it possible to reduce the response time of the microsensor.

Preferably again, the arrangement of the microsensor according to the invention, preferably again the microsensor according to the invention the ZT_{effective} of which lies between 0.1 and 1.9 and/or the thermal conductivity of which is less than or equal to 10 W.m⁻¹.K⁻¹ and/or the thermal time constant of which, denoted tau, is less than or equal to 10 s makes it possible to obtain a specific detectivity superior to the detectors of the prior art. Preferably, the specific detectivity of the microsensor according to the invention is greater than or equal to 1.10⁹ cm.Hz^{0.5}.W⁻¹, preferably 5.10⁹, preferably again 1.10¹⁰, more preferably 5.10¹⁰ and even more preferably 1.10¹¹ cm.Hz^{0.5}.W⁻¹.

Preferably, each of the layers of the at least one pair of layers has a parameter ZT of between 0.1 and 1.9.

Preferably, the ZT of each of the layers of the at least one pair of layers of semiconductor material is greater than or equal to 0.1, preferably again 0.2, preferably 0.3, preferably again 0.4, more preferably 0.5, even more preferably 0.6, particularly preferably 0.7, particularly advantageously 0.8 and very particularly advantageously 0.9. Advantageously the ZT of each of the layers of the at least one pair of layers of semiconductor material is equal to 1.

Preferably, the ZT of each of the layers of the at least one pair of layers of semiconductor material is less than or equal to 1.9, preferably again 1.8, preferably 1.7, preferably again 1.6, more preferably 1.5, even more preferably 1.4, particularly preferably 1.3, particularly advantageously 1.2 and very particularly advantageously 1.1, and preferably above all 1.05.

Layers of the at least one pair of layers having a parameter ZT between 0.1 and 1.9, although constituting an improvement of the invention, can contribute to obtaining a ZT_{effective} close to or equal to 1.

Preferably, a ratio between a thickness, extending along the stacking axis of the layers of the microsensor, of a layer or layers of the at least one pair of layers and, for a layer in question of the at least one pair of layers:
in the first configuration, a distance (R₁-R₂) between the central portion of the layer of metal covering the layer in question and the annular portion of the layer of metal covering the layer in question is less than 0.1%, preferably less than 0.05%, preferably again less than 0.01%, or
in the second configuration, a distance (R₁-R₂) between the central portion of the layer in question and the annular portion of the layer of metal covering the layer in question is less than 0.1%, preferably less than 0.05%, preferably again less than 0.01%; the distance (R₁-R₂) lies in a plane perpendicular to the stacking axis of the layers of the microsensor.

Preferably, the thickness of the at least one pair of layers is less than or equal to 10 μm.

Edge, for example of the microsensor or of a layer, can be understood to mean a border, a peripheral end, a contour or a periphery of the microsensor.

Preferably, the microsensor, preferably again each of the layers of the stack of layers forming the microsensor, has a spherical shape. Preferably, the length of the layers of the at least one pair of layers, preferably again a length of each of the layers of the stack of layers forming the microsensor, extends radially from a centre of the microsensor towards the edge of the microsensor.

The microsensor, preferably again each of the layers of the stack of layers forming the microsensor, can have a rectangular or square shape. Preferably, the length of the layers of the at least one pair of layers, preferably again a length of each of the layers of the stack of layers forming the microsensor, extends along a length or a width of the square or of the rectangle, preferably from a centre of the microsensor towards the edge of the microsensor.

Preferably, the arrangement of the layers of the at least one pair of layers meeting this ratio makes it possible to maximise the temperature gradient, in each of the layers of the at least one pair of layers, between the central portion of the layer of metal and the annular portions of the layer of metal, for the first configuration, and between the central portions of the two layers of the at least one pair of layers and the annular portions of the layer of metal. Preferably, the arrangement of the layers of the at least one pair of layers meeting this ratio makes it possible to minimise the temperature gradient, in each of the layers of the at least one pair of layers, between the layer of metal and the layer of dielectric material. The arrangement of the layers of the at least one pair of layers meeting this ratio, although constituting an improvement of the invention, can contribute to obtaining a ZT_{effective} close to or equal to 1.

Preferably, in the first configuration of the microsensor, a contact surface between the central portion of the metal layer and the at least one pair of layers is greater than 0.1%, preferably again 0.25%, preferably 0.5%, preferably again 0.75%, more preferably 1%, even more preferably 2%, particularly preferably 4%, particularly advantageously 6% and very particularly advantageously 8%, and preferably above all 10%, of a total surface of a face of the at least one pair of layers that is facing the metal layer.

Preferably, in the second configuration of the microsensor, the contact surface between the central portions of the two layers of the at least one pair of layers is greater than 0.1%, preferably again 0.25%, preferably 0.5%, preferably again 0.75%, more preferably 1%, even more preferably 2%, particularly preferably 4%, particularly advantageously 6%, very particularly advantageously 8%, and preferably above all 10%, of a total surface of a face of the at least one pair of layers the central portion of which covers the central portion of the other layer of the at least one pair of layers and/or of a total surface of a face of the layer of the at least one pair of layers the central portion of which is covered by the central portion of the other layer of the at least one pair of layers.

Preferably, a contact surface between the two annular portions of the metal layer and the at least one pair of layers is greater than 10%, preferably again 20%, preferably 30%, preferably again 40%, more preferably 50%, even more preferably 55%, particularly preferably 60%, particularly advantageously 70% and very particularly advantageously 80%, and preferably above all 90%, of a total surface of a face of the at least one pair of layers that is facing the metal layer.

Preferably, such an arrangement of the contact surfaces between the metal layer and the at least one pair of layers, associated with the high thermal and electrical conductivity of the metal layer, makes it possible to reduce the contact resistances between the metal layer and the at least one pair of layers and, furthermore, for the second configuration such an arrangement of the contact surface between the central portions of the two layers of the at least one pair of layers makes it possible to reduce the contact resistances at the contact surface between the central portions of the two layers of the at least one pair of layers. Preferably, such an arrangement of the contact surfaces between the metal layer and the at least one pair of layers, associated with the high thermal and electrical conductivity of the metal layer, and, furthermore, for the second configuration such an arrangement of the contact surface between the central portions of the two layers of the at least one pair of layers makes it possible to homogenise the temperature at the proximal end and at the distal end of the layers of the at least one pair of layers. Preferably, such an arrangement of the contact surfaces between the metal layer and the at least one pair of layers, associated with the high thermal and electrical conductivity of the metal layer, makes it possible to obtain an optimum compromise between a reduction of the contact resistances between the metal layer and the at least one pair of layers, and good homogenisation of the temperature between the metal layer and the at least one pair of layers and, furthermore, for the second configuration such an arrangement of the contact surface between the central portions of the two layers of the at least one pair of layers makes it possible to obtain an optimum compromise between the central portions of the two layers of the at least one pair of layers, and good homogenisation of the temperature between the central portions of the two layers of the at least one pair of layers. Although constituting an improvement of the invention, the arrangement of the contact surfaces between the metal layer and the at least one pair of layers, and, furthermore, for the second configuration the arrangement of the contact surface between the central portions of the two layers of the at least one pair of layers, as described above, associated with the high thermal and electrical conductivity of the metal layer can contribute to obtaining a ZT_{effective} close to 1 or equal to 1.

The microsensor can comprise, at the contact surface between the central portion of the metal layer and the at least one pair of layers, and, for the second configuration, between the central portions of the two layers of the at least one pair of layers, an intermediate thin layer aimed at reducing the contact resistance between the metal layer and the at least one pair of layers, and, for the second configuration, between the central portions of the two layers of the at least one pair of layers. Preferably, the metal layer and/or the at least one pair of layers of semiconductor material can comprise chemical elements constituting the intermediate thin layer that diffused in the metal layer and/or in the at least one pair of layers of semiconductor material.

Preferably, the materials constituting the layers of the at least one pair of layers are:
semiconductor materials comprising telluride and/or bismuth and/or germanium and/or antimony, and/or
Heusler alloys.

Preferably, the semiconductor material constituting the at least one pair of layers comprises or consists of at least 90%, as an atomic percentage, of bismuth telluride or germanium telluride or lead telluride or antimony telluride or an antimony-lead alloy or a silicon-germanium alloy.

Preferably, for a measurement temperature of around 300 K, the semiconductor material is bismuth telluride.

Preferably, for a measurement temperature of around 700 K, the semiconductor material is an alloy comprising telluride, antimony, germanium and silver or an alloy comprising lead and telluride.

Preferably, for a measurement temperature of around 900 K, the semiconductor material is an alloy comprising zinc and antimony or derivatives thereof or skutterudite.

Preferably, for a measurement temperature of around 1200 K, the semiconductor material is an alloy comprising silicon and germanium.

Preferably, the at least one pair of layers rests entirely on the layer of dielectric material.

Preferably, the whole of a surface or of a face of the at least one pair of layers that is facing the layer of dielectric material is in contact with the dielectric material.

Preferably, the characteristic of the microsensor according to which all the layers of the at least one pair of layers are in contact with the layer of dielectric material makes it possible to reduce the electrical losses or exchanges and/or the thermal losses or exchanges of the layers of the at least one pair of layers with the environment of the microsensor. Such an arrangement of the layers of the at least one pair of layers, although constituting an improvement of the invention, can contribute to obtaining a ZT_{effective} close to or equal to 1.

Preferably, the microsensor comprises a layer of absorbent material covering, preferably coming solely:
in the first configuration, the central portion of the layer of metal, or
in the second configuration, the central portion of the layer of the at least one pair of layers covering the central portion of the other layer of the at least one pair of layers, said layer of absorbent material is able to absorb heat over a wide range of wavelengths.

Preferably, the layer of absorbent material covers a top surface of the central portion of the layer of metal or a top surface of the layer of the at least one pair of layers covering the central portion of the other layer of the at least one pair of layers.

Wide range of wavelengths can be understood to mean wavelengths between around a hundred nanometres and a few hundreds of microns.

The absorbent material can be a dielectric material. The absorbent material can be carbon black, black gold or platinum black.

Preferably, the microsensor is arranged and/or comprises securing means intended or able to cooperate with a vacuum chamber so that the at least one pair of layers of semiconductor material and the layer of metal and/or the layer of absorbent material and/or the layer of dielectric material and/or the support made of thermally conductive material are maintained under primary or secondary vacuum. Preferably, the use of the microsensor under ambient pressure conditions offers sensitivities and detection thresholds below those of the prior art. The use of the microsensor under vacuum is not necessary but makes it possible to further improve the sensitivity and the detection threshold of the microsensor.

Preferably, a thickness, extending along the stacking axis of the layers of the microsensor, of the layers of the at least one pair of layers and/or a thickness, extending along the stacking axis of the layers of the microsensor, of the central portion and/or of the annular portions of the layer of metal is between 0.01 and 10 μm and/or a thickness, extending along the stacking axis of the layers of the microsensor, of the layer of absorbent material is between 0.1 and 10 μm.

Preferably, the thicknesses of the layers of the stack of layers of the microsensor as described above make it possible to reduce, preferably to make negligible, the temperature gradient, in each of the layers of the stack of layers of the microsensor, along the stacking axis of the layers of the microsensor. Preferably, the thicknesses of the layers of the stack of layers of the microsensor as described above make it possible to maximise the temperature gradient, in each of the layers of the at least one pair of layers, between the central portion of the layer of metal and the annular portions of the layer of metal, for the first configuration, or between the central portions of the two layers of the at least one pair of layers and the annular portions of the layer of metal, for the second configuration. The thicknesses of the layers of the stack of layers of the microsensor as defined above, although constituting an improvement of the invention, can contribute to obtaining a ZT_{effective} close to or equal to 1.

Preferably, the support made from thermally conductive material is annular and extends along a periphery of the bottom face of the microsensor.

Preferably, the effect of the annular support made from thermally conductive material extending along the periphery of the bottom face of the microsensor makes it possible to generate a temperature gradient extending radially from the centre of the microsensor, where the power of the thermal radiation is absorbed, towards the periphery of the circumference of the microsensor.

Preferably, a thickness, extending along the stacking axis of the layers of the microsensor, of the part of the layer of dielectric material that is facing the annular support made from thermally conductive material is greater than the thickness of the rest of the layer of dielectric material. In other words, preferably, a thickness of the layer of dielectric material varies in the plane perpendicular to the stacking axis of the layers of the microsensor. Preferably, the layer of dielectric material comprises a so-called central part and an annular part that extends along a periphery of the layer of dielectric material. Preferably, the rest of the layer of dielectric material corresponds to the central part of the layer of dielectric material. Preferably, the annular part of the layer of dielectric material corresponds to the part of the layer of dielectric material that is facing the annular support made from thermally conductive material. Preferably, the central part of the layer of dielectric material extends from a centre of the layer of dielectric material as far as the annular part of the layer of dielectric material. Preferably, the centre of the layer of dielectric material coincides or is merged with the axis of revolution of the microsensor.

Preferably, the thickness of the annular part of the layer of dielectric material has a thickness greater than the thickness of the central part of the layer of dielectric material.

Preferably, the thickness of the rest of the layer of dielectric material is less than 20 μm, preferably again less than 18 μm, preferably less than 16 μm, preferably again less than 14 μm, more preferably less than 12 μm, even more preferably less than 10 μm. Preferably, the thickness of the rest of the layer of dielectric material is less than 9 μm, preferably again less than 8 μm, preferably less than 7 μm, preferably again less than 6 μm, more preferably less than 5 μm, even more preferably less than 4 μm, particularly preferably less than 3 μm, particularly advantageously less than 2 μm and preferably above all less than 1 μm.

Preferably, the dielectric material can comprise solely an annular part. In other words, the dielectric material may not comprise a central part.

Preferably, the thickness of the layer of dielectric material that is facing the annular support made from thermally conductive material is between 1 and 100 μm, preferably again between 12.5 and 50 μm.

Preferably, a length of the layer of dielectric material and/or a length of the support made from thermally conductive material is greater than a length of the other layers of the stack of layers of the microsensor; for each of the layers of the stack of layers of the microsensor, the length of a layer in question of the stack of layers of the microsensor is included in a plane perpendicular to the stacking axis of the layers of the microsensor and extends between a central portion and an edge, preferably an external edge, of the layer in question.

Preferably, the length of a layer in question of the stack of layers of the microsensor extends between a so-called proximal end, located on the same side as the centre of the microsensor, and a so-called distal end, located on the same side as the external edge, of the layer in question.

Preferably, the layer of dielectric material and/or the support made from thermally conductive material extend, radially or in the direction connecting the centre of the microsensor to the edges of the microsensor, beyond the other layers of the stack so as to prevent a short-circuit between the at least one pair of layers and/or the layer of metal and the support made from thermally conductive material.

According to the invention, a method for manufacturing a microsensor according to the invention is also proposed. The method comprises the steps consisting in:
depositing a layer consisting of a dielectric material on a support made from thermally conductive material,
implementing a first succession of microfabrication steps to form a first layer of a pair of layers, intended to form a thermocouple, covering a first part of the layer of dielectric material,
implementing a second succession of microfabrication steps to form a second layer of the pair of layers, intended to form a thermocouple, covering a second part of the layer of dielectric material, the first and second layers of the pair of layers are separated, by a trench, by a minimum distance greater than 500 nm,
implementing a third succession of microfabrication steps to form a layer of metal partially covering the pair of layers, the layer of metal comprises two annular portions per pair of layers, one of the two annular portions covers a peripheral portion of one of the two layers of the pair of layers and the other one of the two annular portions covers a peripheral portion of the other one of the two layers of the pair of layers;
   in a first configuration of the microsensor, the layer of metal comprises a central portion that covers at least a portion of each of the two layers of the pair of layers that is adjacent to the trench, and
   in a second configuration of the microsensor, a central portion of the second layer of the pair of layers covers a central portion of the first layer of the pair of layers.

The method for obtaining the microsensor can also comprise one or more steps of treating the contact surface between the metal layer and the pair of layers making it possible to reduce the contact resistances between the metal layer and the pair of layers of semiconductor material. Preferably, such a treatment aims to reduce the contact resistance between the metal layer and the layers of semiconductor material.

The method according to the invention is particularly adapted, preferably again specially designed, to use the microsensor according to the invention. Thus any characteristic of the microsensor according to the invention can be incorporated in the method according to the invention and vice versa.

### DESCRIPTION OF THE FIGURES

Other advantages and particularities of the invention will appear upon reading the detailed description of non-limiting implementations and embodiments, and from the following appended drawings:

FIG. 1 is a schematic representation in a plan view of a first embodiment of the thermoelectric microsensor according to the invention,

FIG. 2 the FIGURE is a schematic representation in a view in cross section of the microsensor illustrated on FIG. 1,

FIG. 3 is a schematic representation in a view in cross section of the microsensor illustrated on FIG. 1,

FIG. 4 is a schematic representation in a view in cross section of the microsensor illustrated on FIG. 1,

FIG. 5 is a schematic representation in a plan view of a second embodiment of a thermoelectric microsensor according to the invention,

FIG. 6 is a schematic representation in a view in cross section of the microsensor illustrated on FIG. 5,

FIG. 7 is a schematic representation in a view in cross section of the microsensor illustrated on FIG. 5,

FIG. 8 is a graph illustrating the temperature variations over time of a black body measured by the microsensor,

FIG. 9 is a graph illustrating the temperature variations over time of a black body measured by the microsensor,

FIG. 10 is a graph illustrating the variations in thermal powers over time of a light-emitting diode measured by the microsensor,

FIG. 11 is a graph illustrating the variations in thermal powers over time of a light-emitting diode measured by the microsensor,

FIG. 12 is a graph illustrating the variations in thermal powers over time of a light-emitting diode measured by the microsensor,

FIG. 13 is a graph illustrating the variations in thermal powers over time of a light-emitting diode measured by the microsensor.

### DESCRIPTION OF THE EMBODIMENTS

The embodiments described hereinafter being in no way restrictive, variants of the invention comprising only a selection of the described features, isolated from the other described features (even though this selection is isolated within a sentence comprising these other features) could be considered in particular, if this selection of features is sufficient to confer a technical advantage or to differentiate the invention with regards to the prior art. This selection comprises at least one feature, preferably a functional feature with no structural details, or with only part of the structural details if this portion alone is sufficient to confer a technical advantage or to differentiate the invention with regards to the prior art.

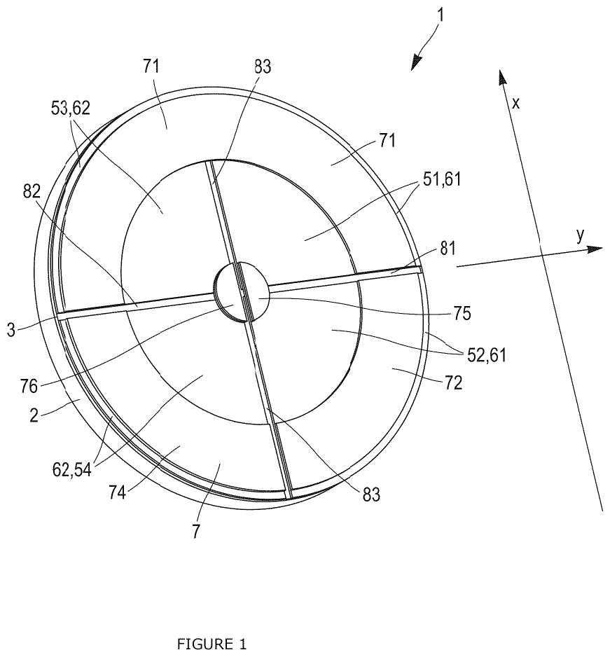

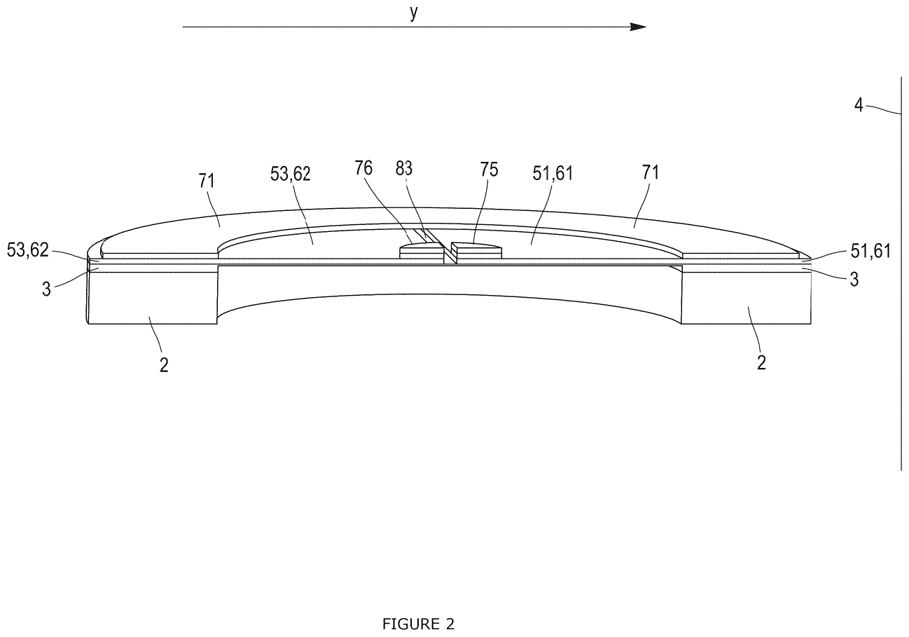

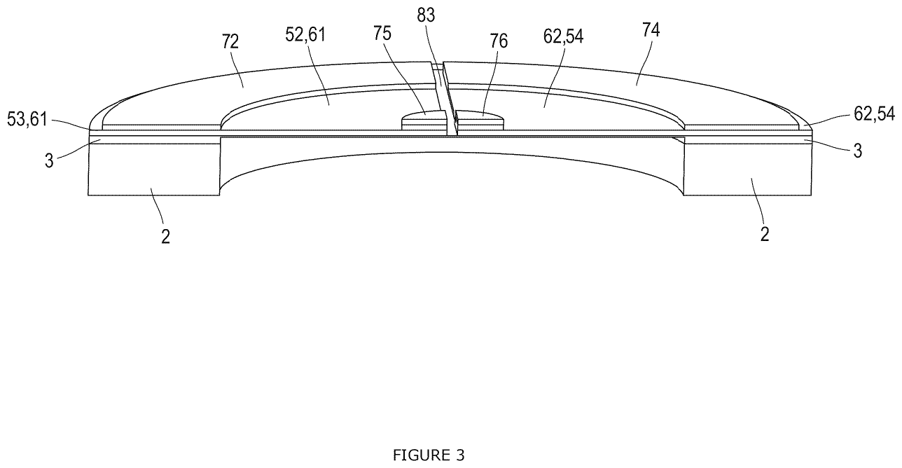

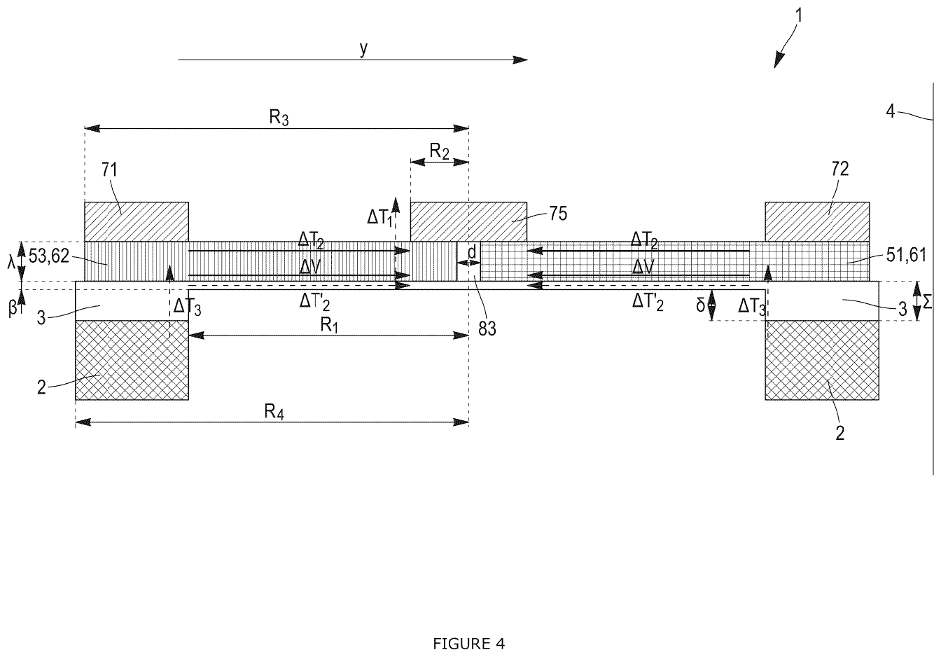

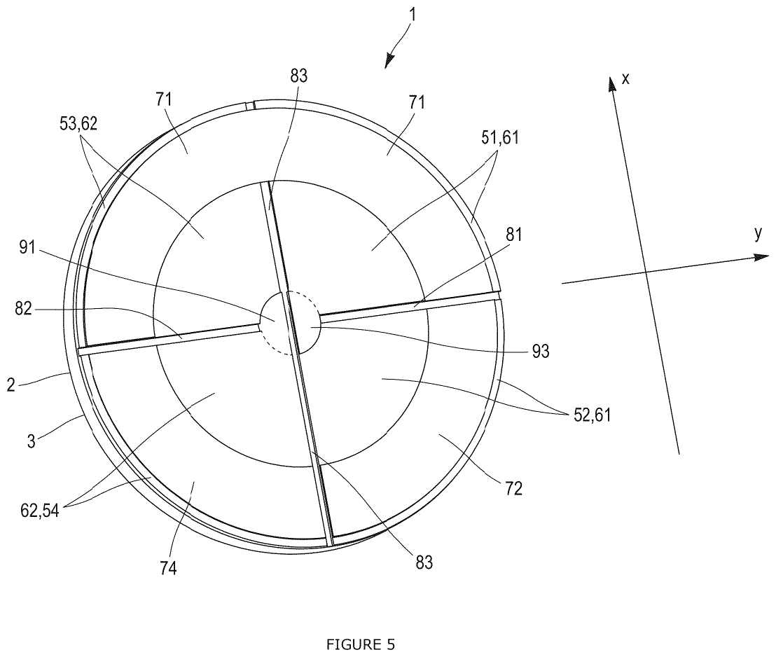

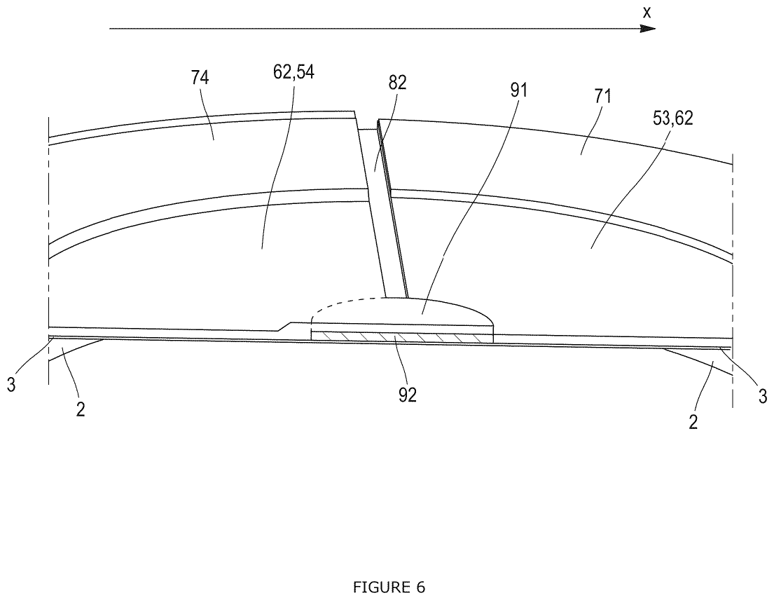

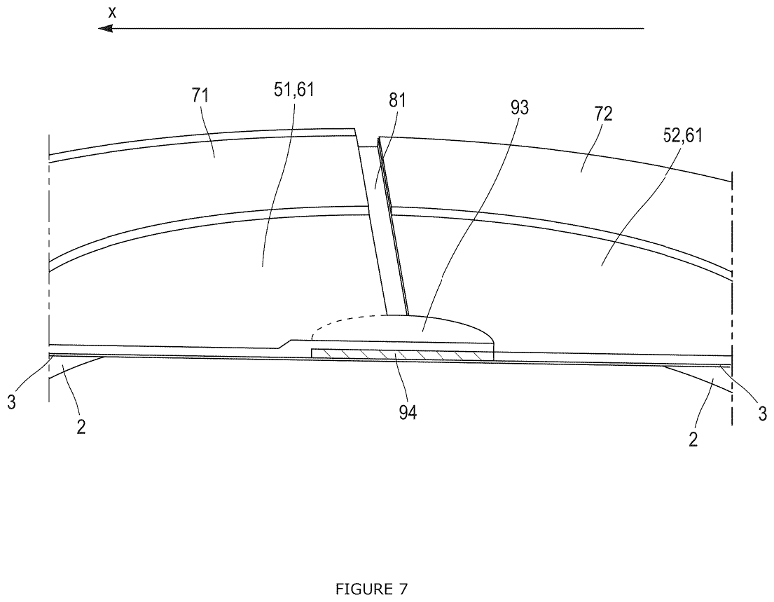

With reference to FIGS. 1 to 7, a thermoelectric microsensor 1 according to the invention is presented. The microsensor 1 is formed by a stack of layers. The microsensor 1 is circular according to the embodiment presented. This geometry is not limitative and the arrangement now described can be transposed directly to a microsensor 1 with any shape, for example square or rectangular. As described below, the centre or the central part of the microsensor 1 constitutes the detection zone onto which the thermal radiation to be detected is directed. According to the non-limitative embodiment, the detection zone is located on the top face of the microsensor 1. The detection zone could very well be located at the centre of the bottom face of the microsensor 1.

The stack of layers comprises a support 2 made from thermally conductive material. The support 2 constitutes the bottom layer of the microsensor 1. According to the embodiment, the support 2 is made from copper. The stack of layers comprises a layer 3 consisting of a dielectric material that rests on the copper support 2. The layer 3 of dielectric material is made from Kapton according to the embodiment. The stack of layers comprises at least one pair of layers, to pairs 51, 52 and 53, 54 of layers 51, 52, 53, 54 according to the embodiment, forming a thermocouple, two thermocouples 61, 62 according to the embodiment. Each layer of a pair 51, 52 and 53, 54 of layers is separated by a trench 83 from a layer of another pair 51, 52 and 53, 54 of layers. In other words, the layer 51 of the thermocouple 61 is separated by the trench 83 from the layer 53 of the thermocouple 62 and the layer 52 of the thermocouple 61 is separated by the trench 83 from the layer 54 of the thermocouple 62. The stack of layers comprises a layer of metal 71, 72, 74, 75, 76 partially covering the two pairs 51, 52 and 53, 54 of layers 51, 52, 53, 54. The layer of metal 71, 72, 74, 75, 76 comprises two annular portions 71, 72 and 71, 74 per pair 51, 52 and 53, 54 of layers 51, 52, 53, 54. According to the embodiment, the layer of metal 71, 72, 74, 75, 76 therefore comprises three annular portions 71, 72, 74. For each thermocouple 61, 62, one of the two annular portions 71, 72 or 71, 74 of a thermocouple 61, 62 covers a peripheral portion of one of the two layers 51 or 52 and 53 or 54 of one of the two pairs 51, 52 and 53, 54 of layers, and the other one of the two annular portions 71, 72 or 71, 74 covers a peripheral portion of the other layer 51 or 52 and 53 or 54 of the two pairs 51, 52 or 53, 54 of layers. The thickness of the layer of metal is 1 μm according to the non-limitative embodiment. The layer of metal 71, 72, 74, 75, 76 is a bilayer of nickel-platinum according to the non-limitative embodiment.

Each thermocouple 61, 62 or each pair 51, 52 and 53, 54 of layers is arranged so that a trench 81, 82 separates the two layers 51, 52 and 53, 54 of a thermocouple 61, 62. The width of the trench 81, 82, denoted d, or the distance separating the two layers 51, 52 and 53, 54 of a thermocouple 61, 62 is 500 μm according to the non-limitative embodiment.

With reference to FIGS. 1 to 4, in a first configuration of the microsensor 1 according to the embodiment, the layer of metal 71, 72, 74, 75, 76 comprises two central portions 75, 76. In practice, the microsensor 1 comprises one central portion 75, 76 per thermocouple 61, 62. Each of the central portions 75, 76 covers a portion, which is adjacent to the trench 81, 82, of each of the two layers 51, 52 and 53, 54 of a thermocouple 61, 62. The central portions 75, 76 of the layer of metal have the effect of electrically connecting the two layers 51, 52 and 53, 54 of a thermocouple 61, 62. The central portions 75, 76 of the layer of metal are located in the detection zone of the microsensor 1. Furthermore, the central portions 75, 76 of the layer of metal 71, 72, 74, 75, 76 also have the effect of homogenising the temperature at each portion adjacent to the trench 81, 82, of each of the two layers 51, 52 and 53, 54 of a thermocouple 61, 62. Finally, the central portions 75, 76 of the layer of metal 71, 72, 74, 75, 76 also have the effect of allowing better absorption of the thermal radiation.

With reference to FIGS. 5 to 7, a second configuration of the microsensor 1 according to the embodiment is illustrated. The second configuration of the microsensor 1 differs from the first configuration of the microsensor 1 solely in the central zone of the microsensor 1 and solely with regard to the two layers 51, 52, 53, 54 of the thermocouples 61, 62. Only the differences between the two configurations are therefore presented. Unless indicated to the contrary, all the features described apply to the two configurations of the microsensor 1. In the second configuration of the microsensor 1 according to the embodiment, a central portion 91, 93 of a layer 51, 54 from the two layers 51, 52 and 53, 54 of each thermocouple 61, 62 covers a central portion 92, 94 of the other layer 52, 53. Covering the central portions 91, 92 and 93, 94 of the layers 51, 52 and 53, 54 of each thermocouple 61, 62 has the effect of electrically connecting the two layers 51, 52 and 53, 54 of a thermocouple 61, 62. The central portions 91, 92, 93, 94 of the layers 51, 52 and 53, 54 are located in the detection zone of the microsensor. Furthermore, covering the central portions 91, 92, 93, 94 of the layers 51, 52 and 53, 54 of each thermocouple 61, 62 also has the effect of homogenising the temperature at each of the portions of the central portions 91, 92.

According to the invention, the materials constituting each of the layers two layers 51, 52, 53, 54 of each thermocouple 61, 62 are selected so that, for a given interval of measurement temperatures, denoted [Tₘᵢₙ, Tₘₐₓ], the microsensor 1 has a parameter ZT_{effective} of between 0.1 and 1.9, ZT is the merit factor of the microsensor and T is the measurement temperature. It was observed that the design of a microsensor 1 respecting the arrangement as described above, the ZT_{effective} is close to 1 or equal to 1, makes it possible to obtain the best sensitivity and the best detection threshold. The arrangement of the layers of the stack of layers of the microsensor 1 modifies the ZT_{effective} of the microsensor 1. In particular, the arrangement of the layers of the stack of layers modifies, among other things, the thermal conductivity and the electrical conductivity of the layers 51, 52 and 53, 54 of the thermocouples 61, 62 and therefore their merit factor. Thus it is necessary for the selection of the materials constituting the layers 51, 52 and 53, 54 of the thermocouple 61, 62 to take account of the arrangement of the stack of layers of the microsensor 1 overall. Thus this effect is not, and is not to be, obtained by simply selecting the materials constituting the layers 51, 52 and 53, 54 of a thermocouple 61, 62 so that the merit factor of the pairs of layers 51, 52 and 53, 54 of the thermocouples 61, 62 is as high as possible or a small as possible. Thus, by way of non-limitative example, according to the embodiment, and for an operating temperature of around 300 kelvins, the material used for the layers 51 and 54 of the thermocouples 61, 62 is p-doped bismuth (III) telluride, (Bi₂Te_{2.7}Se_{0.3}), and the layers 52 and 53 of the thermocouples 61, 62 are made from n-doped bismuth telluride (Bi_{0.5}Sb_{1.5}Te₃). In the case of bismuth telluride, the merit factor of the layers 51, 52, 53, 54 of the thermocouples 61, 62 is of the order of 1 and the merit factor of the microsensor 1 is of the order of 1.

In practice, according to the embodiment with two thermocouples 61, 62, the temperature is measured by measuring the potential difference that is established between the annular portions 72 and 74. The potential difference measured therefore corresponds to the potential difference at the terminals of the two thermocouples 61, 62 connected in series.

For the first configuration, the central portion 75 connects the layer 52 to the layer 51 of the pair of layers 51, 52 of the thermocouple 61, the annular portion 71 connects the thermocouple 61 to the thermocouple 62 and the central portion 76 connects the layer 53 to the layer 54 of the pair of layers 53, 54 of the thermocouple 62.

For the second configuration, the central portions 93, 94 connect the layer 52 to the layer 51 of the pair of layers 51, 52 of the thermocouple 61, the annular portion 71 connects the thermocouple 61 to the thermocouple 62 and the central portions 91, 92 connect the layer 53 to the layer 54 of the pair of layers 53, 54 of the thermocouple 62.

This operating mode is transposable and adapted to the numbers of thermocouples constituting the microsensor. In particular, for a microsensor comprising two thermocouples or more and comprising a total number N of layers forming the pairs of layers of the microsensor, the microsensor will comprise a number of annular portions connecting two adjacent layers each belonging to a pair of distinct layers is equal to ((N−2)/2). Such a microsensor will comprise a number denoted M of thermocouples that is equal to (N/2) and a number of annular portions N′ that is equal to 2M+1.

In an improvement of the microsensor 1, the support 2 is annular. The thickness of the support 2 is 2 mm according to the embodiment. Such a thickness makes it possible to have, at the support, a high thermal mass that defines a constant temperature. The arrangement of the support 2 makes it possible to maximise the radial temperature gradient, denoted ΔT2, extending laterally or perpendicularly with respect to the layer-stacking axis 4, being established in the microsensor 1 when a thermal radiation is absorbed at the centre of the microsensor 1. Optimising the temperature gradient ΔT2 will cause an increase in the potential difference, denoted ΔV, measured at the terminals of the thermocouples 61, 62, i.e. between the annular portions 71, 72 and 71, 74 of the layer of metal of a thermocouple 61, 62, and will therefore increase the sensitivity and decrease the detection threshold of the microsensor 1.

In an improvement of the microsensor 1, the layer 3 has a thickness that varies laterally or radially. The thickness Σ of the part of the layer 3 facing the annular support 2 is 25 μm. This thickness must be sufficient to provide electrical insulation between the metal layer 71, 72 and 71, 74 and 75, 76 and the layers 51, 52, 53, 54 of the thermocouples 61, 62 and the support 2. Such an arrangement of the layer 3 makes it possible to reduce the temperature gradient ΔT3 between the support 2 and the layers 51, 52, 53, 54 of the thermocouples 61, 62 so as to maximise the temperature gradient ΔT2.

Furthermore, the thickness β of the part of the layer 3 extending from the centre of the microsensor 1 as far as the interior of the proximal edge of the support 2, i.e. the part having a diameter equal to twice R₁, is 1 μm. This thickness must be as small as possible to reduce the lateral temperature gradient ΔT′2 in the layer 3 so as to maximise the lateral temperature gradient ΔT2 in the layers 51, 52, 53, 54 of the thermocouples 61, 62. Ideally, the layers 51, 52, 53, 54 of the thermocouples 61, 62 are suspended and the layer 3 is annular.

In an improvement of the microsensor 1, the length or radius R₄ of the layer 3 is equal to the length R₄ of the support 2. The radius R₄ of the layer 3 is greater than the radius R₃ of the layers 51, 52, 53, 54 of the thermocouples 61, 62 and greater than the radius of the annular portions 71, 72 and 71, 74 of the layer of metal. In other ways, the distal end of the layer 3 extends radially beyond the distal end of the layers 51, 52, 53, 54 of the thermocouples 61, 62 and beyond the distal end at the radius R₃-R₁ of the annular portions 71, 72 and 71, 74 of the layer of metal. This has the effect of prevent-ing a short-circuit between layers 51, 52, 53, 54 of the thermocouples 61, 62 and/or the annular portions 71, 72 and 71, 74 of the layer of metal and the copper support 2.

In an improvement of the microsensor 1, a ratio between the thickness λ of the layers 51, 52, 53, 54 of the thermocouples 61, 62 and the length, equal to R₁-R₂, of the layers 51, 52, 53, 54 of the thermocouples 61, 62 is less than 0.1%. The ratio is of the order of 0.01% according to the embodiment. An arrangement respecting such a ratio makes it possible to maximise the lateral temperature gradient ΔT2 in the layers 51, 52, 53, 54 of the thermocouples 61, 62. In addition, an arrangement respecting such a ratio makes it possible to minimise the vertical temperature gradient ΔT3 between the layers 51, 52, 53, 54 of the thermocouples 61, 62 and the layer 3. Furthermore, for the first configuration, an arrangement respecting such a ratio makes it possible to minimise the vertical temperature gradient ΔT1 between the layers 51, 52, 53, 54 of the thermocouples 61, 62 and the central portions 75, 76 of the layer of metal.

In an improvement of the microsensor 1, the thermal time constant, denoted tau, of the microsensor 1 is less than or equal to 10 s. Such a time constant is obtained by virtue of the arrangement of the layers of the stack of layers of the microsensor 1 as defined above. Such a thermal time constant makes it possible to reduce the response time of the microsensor 1.

In an improvement of the microsensor 1, the arrangement of the microsensor according to the invention makes it possible to obtain a specific detectivity superior to the detector of the prior art. This specific detectivity is between 1.10⁹ and 1.10¹¹ cm.Hz^{0.5}.W⁻¹ according to the embodiment. Unlike the detector of the prior art, the specific detectivity of the microsensor 1 according to the invention depends only on the thickness A of the layers 51, 52, 53, 54 of the thermocouples 61, 62 and is inversely proportional to the thickness λ of the layers 51, 52, 53, 54 of the thermocouples 61, 62. Consequently, the smaller the thickness λ, the higher the specific detectivity of the microsensor 1.

In an improvement of the microsensor 1, a contact surface between the annular portions 71, 72 and 71, 74 of the layer of metal and the layers 51, 52, 53, 54 of the thermocouples 61, 62 is greater than 10% of the total surface of the top face of the layers 51, 52, 53, 54 of the thermocouples 61, 62 that is facing the metal layer. The ratio between the contact surface between the annular portions 71, 72 and 71, 74 of the layer of metal and the layers 51, 52, 53, 54 of the thermocouples 61, 62 and the total surface of the top face of the layers 51, 52, 53, 54 of the thermocouples 61, 62 that is facing the metal layer is 55% according to the embodiment. Such a ratio has the effect of reducing the contact resistances between the annular portions 71, 72 and 71, 74 of the layer of metal and the layers 51, 52, 53, 54 of the thermocouples 61, 62. Such a ratio also has the effect of homogenising the temperature at the distal end of the layers 51, 52, 53, 54 of the thermocouples 61, 62. Such a ratio also makes it possible to obtain an optimum compromise between a reduction in the contact resistances between the annular portions 71, 72 and 71, 74 of the layer of metal and the layers 51, 52, 53, 54 of the thermocouples 61, 62 and a good thermal transfer between the annular portions 71, 72 and 71, 74 of the layer of metal and the layers 51, 52, 53, 54 of the thermocouples 61, 62.

In an improvement of the first configuration of the microsensor 1, the contact surface between the central portions 75, 76 of the layer of metal and the layers 51, 52, 53, 54 of the thermocouples 61, 62 is greater than 0.1% of the total surface of the top face of the layers 51, 52, 53, 54 of the thermocouples 61, 62. The ratio is of the order of 2% according to the embodiment. Such a ratio has the effect of reducing the contact resistances between the central portions 75, 76 of the layer of metal and the layers 51, 52, 53, 54 of the thermocouples 61, 62. Such a ratio also has the effect of homogenising the temperature at the proximal end of the layers 51, 52, 53, 54 of the thermocouples 61, 62. Such a ratio also makes it possible to obtain an optimum compromise between a reduction in the contact resistances between the central portions 75, 76 of the layer of metal and the layers 51, 52, 53, 54 of the thermocouples 61, 62 and a good thermal transfer between the annular portions 75, 76 of the layer of metal and the layers 51, 52, 53, 54 of the thermocouples 61, 62.

In an improvement of the second configuration of the microsensor 1, the contact surface between the central portions 91, 92 and 93, 94 of the layers 51, 52, 53, 54 of the thermocouples 61, 62 is greater than 0.1% of the total surface of a top face of the layers 51, 52, 53, 54 of the thermocouples 61, 62. The ratio between the contact surface between the central portions 91, 92 and 93, 94 of the layers 51, 52, 53, 54 of the thermocouples 61, 62 and the total surface of a top face of the layers 51, 52, 53, 54 of the thermocouples 61, 62 is 2% according to the embodiment. Such a ratio has the effect of reducing the contact resistances between the central portions 91, 92 and 93, 94 of the layers 51, 52, 53, 54 of the thermocouples 61, 62. Such a ratio also has the effect of homogenising the temperature at the central portions 91, 92 and 93, 94 of the layers 51, 52, 53, 54 of the thermocouples 61, 62. Such a ratio also makes it possible to obtain an optimum compromise between a reduction in the contact resistances between the central portions 91, 92 and 93, 94 of the layers 51, 52, 53, 54 of the thermocouples 61, 62 and a good thermal transfer between the central portions 91, 92 and 93, 94 of the layers 51, 52, 53, 54 of the thermocouples 61, 62.

Finally, although not necessary for obtaining a ZT_{effective} of the microsensor 1 close to or equal to 1, each of the improvements described above contributes to obtaining a ZT_{effective} close to or equal to 1 by reducing the difference between the merit factor ZT of the pairs of layers 51, 52 and 53, 54 of the thermocouples 61, 62 and the merit factor ZT_{effective} of the microsensor 1.

An embodiment of the method for manufacturing the microsensor 1 according to the invention is also described. The method comprises the step consisting in depositing the layer of Kapton on the annular copper support 2. According to the non-limitative embodiment, the Kapton is glued onto the copper support 2, preferably previously cleaned with ethanol. A press is placed on the copper ring and the latter is heated for around ten hours at 120 °C in order to dry the glue.

The method next comprises the step consisting in implementing a first succession of microfabrication steps to form the layers 51 and 54 each covering a first part of the Kapton layer 3. According to the non-limitative embodiment, the first succession of steps comprising a spreading, by spin coating, of S1818 positive resin at a rotation speed of between 6000 rpm/s and 4000 rpm/s for a period of 30 s. The resin is next developed for 1 min in a 1:1 solution of developer Microposit and deionised water. The resin is next insolated. A film of p-type Bi₂Te₃ is deposited by magnetron-assisted cathodic sputtering over the whole of the surface. The resin is next removed by immersing the sample for 5 minutes in acetone and then 5 minutes in ethanol to obtain the layers 51 and 54.

The method next comprises the step consisting in implementing a second succession of microfabrication steps to form the layers 52 and 53 of n-type Bi₂Te₃ covering a second part of the Kapton layer 3. The microfabrication steps implemented are identical to those of the first succession of steps.

The method furthermore comprises an annealing of the layers 51, 52, 53, 54 under argon as a pressure of 600 mbar. The layers 51, 52, 53, 54 are annealed at 270 °C for 2 hours and 3 hours.

The method next comprises the step consisting in implementing a third succession of microfabrication steps to form the three annular portions 71, 72, 74.

For implementing the microsensor 1 according to the first configuration, the third succession of microfabrication steps furthermore comprises the production of the central portions 75, 76 of the layer of metal that cover a portion of each of the two layers of the pair of layers that is adjacent to the trench.

The microfabrication steps implemented during the third succession of steps are identical to those of the first and second successions of steps. The bilayer of nickel-platinum is deposited by X-ray magnetron-assisted cathodic sputtering.

For implementing the microsensor 1 according to the second configuration, the first and second successions of microfabrication steps to form the layers 51, 52, 53 and 54 are implemented so that the central portions 91, 93 of the second layer of the pair of layers covers the central portion 92, 94 of the first layer of the pair of layers.

In a particular embodiment of the invention, the dimensions of the microsensor 1 are reduced, in particular the dimensions R₁, R₂, R₃, R₄ are reduced, by way of non-limitative example, so that the distance 2.R₁ is between 1 mm and 0.01 mm. Thus provision is made for forming a lattice or matrix of microsensors 1, distributed over a two-dimensional surface, thus constituting a thermal camera.

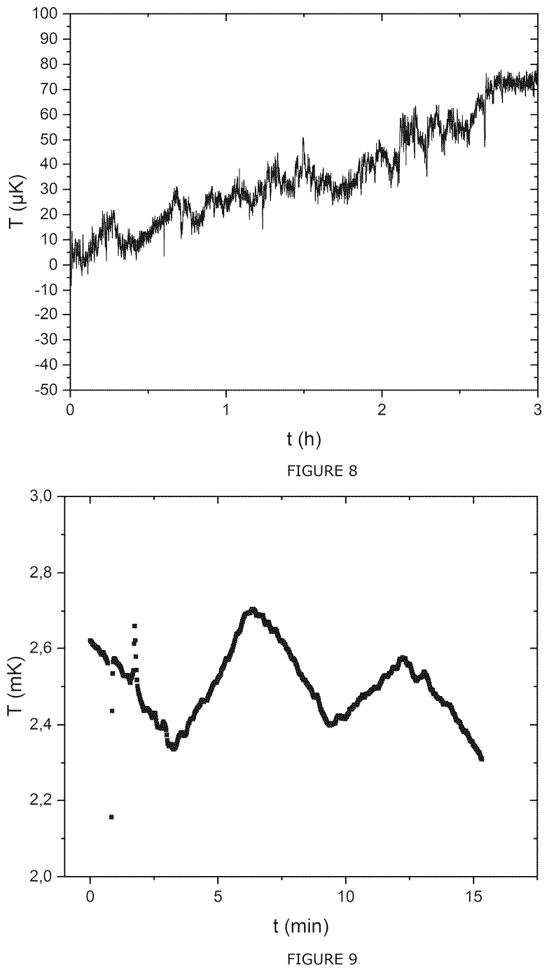

With reference to FIGS. 8 to 13, the performances of the microsensor 1 according to the invention are illustrated.

FIG. 8 presents the temperature variations, measured by the microsensor 1, of a black body with a constant temperature that is placed at a few centimetres from the microsensor 1. The microsensor 1 displays a peak-to-peak noise of less than 10 microkelvins. The drifts are related to the temperature variations of the room in which the microsensor 1 is placed and the black body. They are less than 80 microkelvins over the three hours of the experiment. Each experimental point is a measurement per second of the temperature.

FIG. 9 presents the temperature variations, measured by the microsensor 1, of a black body placed at a few centimetres from the microsensor 1. The temperature variations of the black body are of a few hundreds of microkelvins and are imposed by the experimenter. Each experimental point is a measurement per second of the temperature.

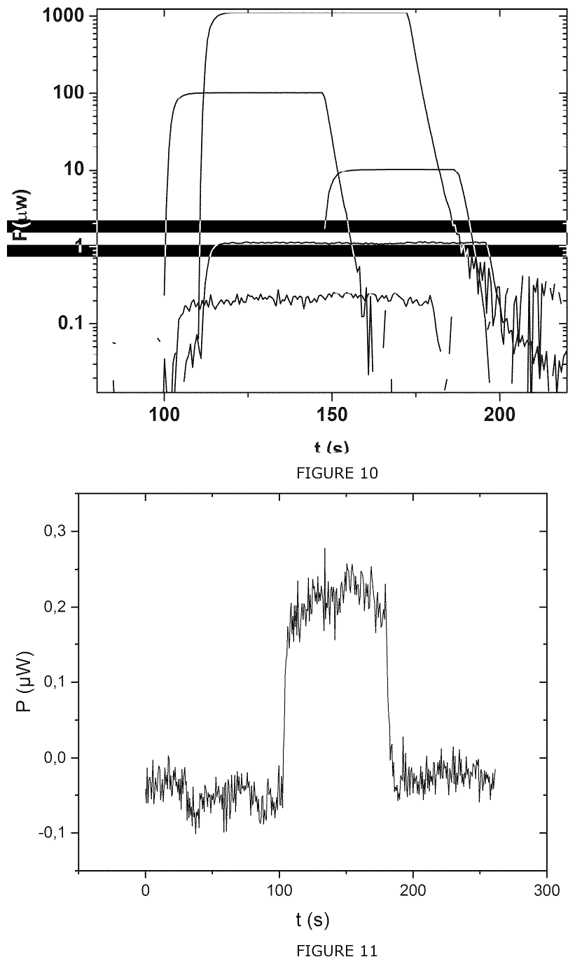

FIG. 10 presents the variations, measured by the microsensor 1, in the thermal power supplied by a light-emitting diode (LED) emitting at a wavelength of 680 nm. The light emitted by the LED is collimated to the centre of the microsensor 1. The power signal is recorded as a function of time with a point every 1.3 seconds. The microsensor 1 is able to measure variations in the power of the LED of 200 nW, 1 μW, 10 μW, 100 μW and 1 mW. The measurement dynamic range over time is presented to a logarithmic scale. It was observed that the microsensor 1 has a top measurable-power limit of 600 mW.

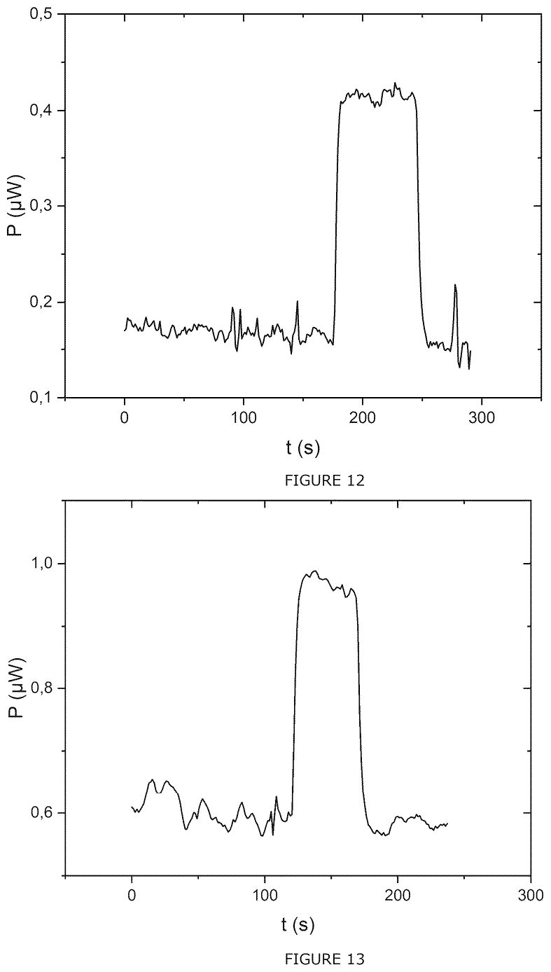

FIGS. 11, 12 and 13 respectively illustrate the variations, measured by the microsensor 1, in the value of the thermal power supplied by LEDs emitting respectively at 680, 1050 and 1650 nm. The light emitted by the LEDs is collimated to the centre of the microsensor 1. The power signal is illustrated as a function of time with a point recorded every 0.64, 1.3 and 1.3 seconds respectively. With reference to FIG. 11, the microsensor 1 is capable of measuring a variation in the power of the LED of approximately 250 nW with a peak-to-peak noise of approximately 50 nW. With reference to FIG. 12, the microsensor 1 is capable of measuring a variation in the power of the LED of approximately 250 nW with a peak-to-peak noise of approximately 50 nW. With reference to FIG. 13, the microsensor 1 is capable of measuring a variation in the power of the LED of approximately 350 nW with a peak-to-peak noise of approximately 50 nW.

Of course, the invention is not limited to the examples that have just been described and many arrangements could be made to these examples without departing from the scope of the invention.

Thus, in variants that could be combined together of the previously-described embodiments:
in the second configuration of the microsensor 1, the layer of metal furthermore covers the central portions 91, 93 of the layers 51, 54, and/or
in the second configuration, the microsensor 1 comprises a layer of absorbent material covering the central portions 91, 93 of the layers 51, 54 or covering the layer of metal that covers the central portions 91, 93 of the layers 51, 54, and/or
in the first configuration, the microsensor 1 comprises a layer of absorbent material covering the central portions 75, 76 of the layer of metal.

In addition, the various features, shapes, variants and embodiments of the invention may be associated with each other according to various combinations to the extent that they are not incompatible or exclusive of one another.

1. Thermoelectric microsensor for measuring low-power thermal radiations, referred to as a microsensor, formed by a stack of layers comprising, from a bottom face to a top face of the microsensor:
a support made from thermally conductive material,
a layer consisting of a dielectric material,
at least one pair of layers forming a thermocouple the at least one pair of layers is separated by a minimum distance greater than 500 nm by a trench,
a layer of metal partially covering the at least one pair of layers, the layer of metal comprises two annular portions per pair of layers and for each thermocouple in question one of the two annular portions covers a peripheral portion of one of the two layers of the at least one pair of layers and the other one of the two annular portions:
covers a peripheral portion of the other layer of the at least one pair of layers, and
for a number of thermocouples greater than or equal to 2, is connected to a peripheral portion of an adjacent layer belonging to a distinct thermocouple;
in a first configuration of the microsensor, the layer of metal comprises a central portion that covers at least one portion, of each of the two layers of the at least one pair of layers that is adjacent to the trench, or
in a second configuration of the microsensor, a central portion of one of the two layers of the at least one pair of layers covers at least a central portion of the other layer of the at least one pair of layers;
said microsensor has, for a given interval of measurement temperatures, denoted [Tₘᵢₙ, Tₘₐₓ], a parameter ZT_{effective} of between 0.1 and 1.9, ZT is the merit factor of the microsensor and T is the measurement temperature.

2. Microsensor according to claim 1, wherein a thermal conductivity of the microsensor is less than or equal to 10 W.m⁻¹.K⁻¹.

3. Microsensor according to claim 2, wherein a thermal time constant, denoted tau, of the microsensor is less than or equal to 10 s, tau is equal to the ratio between a calorific capacity of the microsensor and the thermal conductivity of the microsensor.

4. Microsensor according to claim 1, wherein each of the layers of the at least one pair of layers has a parameter ZT of between 0.1 and 1.9.

5. Microsensor according to claim 1, wherein a ratio between a thickness, extending along the stacking axis 4 of the layers of the microsensor, of the layers of the at least one pair of layers and, for a layer in question of the at least one pair of layers:
in the first configuration, a distance between the central portion of the layer of metal covering the layer in question and the annular portion of the layer of metal covering the layer in question is less than 0.1%, or
in the second configuration, a distance between the central portion of the layer of the layer in question and the annular portion of the layer of metal covering the layer in question is less than 0.1%,;
the distance lies in a plane perpendicular to the stacking axis of the layers of the microsensor.

6. Microsensor according to claim 1, wherein:
in the first configuration of the microsensor, a contact surface between the central portion of the metal layer and at least one pair of layers is greater than 0.1% of a total surface of a face of the at least one pair of layers that is facing the metal layer, or
in the second configuration of the microsensor, the contact surface between the central portions of the two layers of the at least one pair of layers is greater than 0.1% of a total surface of a face of the layer of the at least one pair of layers the central portion of which covers the central portion of the other layer of the at least one pair of layers, and/or
a contact surface between the two annular portions of the metal layer and the at least one pair of layers is greater than 10% of a total surface of a face of the at least one pair of layers that is facing the metal layer.

7. Microsensor according to claim 1, wherein, the materials constituting the layers of the at least one pair of layers are:
semiconductor materials comprising telluride and/or bismuth and/or germanium and/or antimony, and/or
Heusler alloys.

8. Microsensor according to claim 7, wherein the semiconductor material comprises bismuth telluride or germanium telluride or lead telluride or antimony telluride or an antimony-lead alloy or a silicon-germanium alloy.

9. Microsensor according to any claim 1, wherein the at least one pair of layers rests entirely on the layer 3 of dielectric material.

10. Microsensor according to claim 1, comprising a layer of absorbent material covering:
in the first configuration, the central portion of the layer of metal, or
in the second configuration, the central portion of the layer of the at least one pair of layers covering the central portion of the other layer of the at least one pair of layers, said layer of absorbent material is able to absorb heat over a wide range of wavelengths.

11. Microsensor according to claim 1, wherein a thickness, extending along the stacking axis 4 of the layers of the microsensor, of the layers of the at least one pair of layers is between 0.01 and 10 μm.

12. Microsensor according to claim 1, wherein a thickness, extending along the stacking axis of the layers of the microsensor, of the central portion and/or of the annular portions of the layer of metal is between 0.01 and 10 μm.

13. Microsensor according to claim 10, wherein a thickness, extending along the stacking axis of the layers of the microsensor, of the layer of absorbent material is between 0.1 and 10 μm.

14. Microsensor according to claim 1, wherein the support made from thermally conductive material is annular and extends along a periphery of the bottom face of the microsensor.

15. Microsensor according to claim 14, wherein a thickness, extending along the stacking axis of the layers of the microsensor, of the part of the layer of dielectric material that is facing the annular support made from thermally conductive material is greater than the thickness of the rest of the layer of dielectric material.

16. Microsensor according to claim 1, wherein a length of the layer of dielectric material and/or a length of the support made from thermally conductive material is greater than a length of the other layers of the stack of layers of the microsensor; each of the layers of the stack of layers of the microsensor, the length of a layer in question of the stack of layers of the microsensor is included in a plane perpendicular to the stacking axis of the layers of the microsensor and extends between a central portion and an edge of the layer in question.

17. Method for manufacturing a microsensor according to claim 1, said method comprises the steps consisting in:
depositing a layer consisting of a dielectric material on a support made from thermally conductive material,
implementing a first succession of microfabrication steps to form a first layer of a pair of layers intended to form a thermocouple covering a first part of the layer of dielectric material,
implementing a second succession of microfabrication steps to form a second layer of the pair of layers, intended to form a thermocouple, covering a second part of the layer of dielectric material, the first and second layers of the pair of layers are separated by a minimum distance, by a trench, greater than 500 nm,
implementing a third succession of microfabrication steps to form a layer of metal partially covering the pair of layers, the layer of metal comprises two annular portions per pair of layers and for each thermocouple in question one of the two annular portions covers a peripheral portion of one of the two layers of the pair of layers and the other one of the two annular portions:
covers a peripheral portion of the other one of the two layers of the pair of layers, and
for a number of thermocouples greater than or equal to 2, is connected to a peripheral portion of an adjacent layer belonging to a distinct thermocouple;
in a first configuration of the microsensor, the layer of metal comprises a central portion that covers at least a portion of each of the two layers of the pair of layers that is adjacent to the trench, and
in a second configuration of the microsensor, a central portion of the second layer of the pair of layers covers a central portion of the first layer of the pair of layers.
